(19) United States
(12) Patent Application Publication
(10) Pub. No.: US 2020/0020777 A1
(43) Pub. Date: Jan. 16, 2020

(54) SiC WAFER AND MANUFACTURING METHOD OF SiC WAFER

(71) Applicants: SHOWA DENKO K.K., Tokyo (JP); DENSO CORPORATION, Kariya-shi, Aichi (JP)

(72) Inventors: Yohei FUJIKAWA, Hikone-shi (JP); Hidetaka TAKABA, Kariya-shi (JP)

(73) Assignees: SHOWA DENKO K.K., Tokyo (JP); DENSO CORPORATION, Kariya-shi, Aichi (JP)

(21) Appl. No.: 16/471,061

(22) PCT Filed: Dec. 22, 2017
(86) PCT No.: PCT/JP2017/046170

§ 371 Date: Jun. 19, 2019

(30) Foreign Application Priority Data
Dec. 26, 2016 (JP) 2016-250804

(51) Int. Cl. H01L 29/16; C30B 23/02; C30B 29/36

(52) U.S. Cl. CPC H01L 29/1608; C30B 29/36; C30B 23/025

(57) ABSTRACT

In a SiC wafer, a difference between a threading dislocation density of threading dislocations exposed on a first surface and a threading dislocation density of threading dislocations exposed on a second surface is 10% or less of the threading dislocation density of the surface with a higher threading dislocation density among the first surface and the second surface, and 90% or more of the threading dislocations exposed on the surface with a higher threading dislocation density among the first surface and the second surface extend to the surface with a lower threading dislocation density.

### TECHNICAL FIELD

The present invention relates to a SiC wafer and a manufacturing method of a SiC wafer.

Priority is claimed on Japanese Patent Application No. 2016-250804, filed on Dec. 26, 2016, the content of which is incorporated herein by reference.

### BACKGROUND ART

Silicon carbide (SiC) has a dielectric breakdown field larger by one order of magnitude and a band gap three times larger than those of silicon (Si). In addition, silicon carbide (SiC) has characteristics such that the thermal conductivity is approximately three times higher than that of silicon (Si). Therefore, application of silicon carbide (SiC) to power devices, high-frequency devices, high-temperature operation devices, and the like is expected.

As a semiconductor device using a SiC epitaxial wafer, a metal-oxide-semiconductor field-effect transistor (MOSFET) is known. In the MOSFET, a gate oxide film is formed on a SiC epitaxial layer by thermal oxidation or the like, and a gate electrode is formed on the gate oxide film. At this time, when there is a defect in a SiC wafer which is a substrate forming a semiconductor device, abnormality may be incurred in the semiconductor device (for example, PTL 1 and the like). Therefore, in order to promote the practical application of semiconductor devices using SiC epitaxial wafers, it is essential to establish high-quality SiC epitaxial wafers and high-quality epitaxial growth techniques.

On the other hand, various defects are present in the SiC epitaxial wafer. Not all the defects adversely affect semiconductor devices. That is, depending on the kind of defect, defects having no or little influence on semiconductor devices are present. For example, it is known that threading dislocations and the like become a cause of failure of a semiconductor device, but it is not precisely known which defect mode can particularly become a killer defect, among the threading dislocations. Therefore, among various defects, it is required to identify defects which have a large influence on a semiconductor device, and suppress the generation of the defects. In this specification, a wafer before epitaxial growth is referred to as a SiC wafer, and a wafer after epitaxial growth is referred to as a SiC epitaxial wafer.

### CITATION LIST

### Patent Literature

[PTL 1] Published Japanese Translation No. 2015-521378 of the PCT International Publication

### SUMMARY OF INVENTION

### Technical Problem

However, identification of which defect mode among threading dislocations can become a killer defect has not progressed sufficiently. This is because threading dislocations that become a cause of failure of a semiconductor device may be combined in a process of crystal growth or may be newly generated in some cases, and it is difficult to specify the cause of the generation of threading dislocations that have an influence on the semiconductor device. In addition, since the semiconductor device is constructed on the surface of the SiC wafer, in order to determine which defect on the surface of the SiC wafer becomes the cause of failure, it is necessary to check the surface state of the SiC wafer by destroying the semiconductor device. However, in order to destroy the semiconductor device, precise processing is necessary, which results in consumption of time and costs. Moreover, there are cases where new scratches and the like are added during destroying.

The present invention has been made taking the foregoing problems into consideration, and an object thereof is to provide a SiC wafer in which a defect that becomes a cause of failure of a semiconductor device can be identified in a nondestructive manner after device construction, and a manufacturing method thereof.

### Solution to Problem

As a result of intensive investigations, the present inventors found that defects which become a cause of failure of a semiconductor device can be identified in a nondestructive manner even after device construction by associating threading dislocations exposed on a first surface and a second surface of a SiC wafer with each other, and completed the present invention. That is, the present invention provides the following means in order to solve the above problems.

(1) According to an aspect of the present invention, in a SiC wafer, a difference between a threading dislocation density of threading dislocations exposed on a first surface and a threading dislocation density of threading dislocations exposed on a second surface is 10% or less of the threading dislocation density of the surface with a higher threading dislocation density among the first surface and the second surface, and 90% or more of the threading dislocations exposed on the surface with a higher threading dislocation density among the first surface and the second surface extend to the surface with a lower threading dislocation density.

(2) In the SiC wafer according to the aspect, the numbers of the threading dislocations of the first surface and the second surface may be substantially the same.

(3) In the SiC wafer according to the aspect, a density of the threading dislocations exposed on the surface with a higher threading dislocation density among the first surface and the second surface may be 1.5 threading dislocations/mm² or less.

(4) In the SiC wafer according to the aspect, the difference between the threading dislocation density exposed on the first surface and the threading dislocation density exposed on the second surface may be 0.02 threading dislocations/mm² or less.

(5) According to another aspect of the present invention, a manufacturing method of a SiC wafer includes: a preparation step of producing a seed crystal having a surface density of threading dislocations of 1.5 threading dislocations/mm² or less; a crystal growth step of performing crystal growth so that a diameter of a crystal does not increase from the seed crystal in a crucible and a crystal growth surface and isotherms in the crucible are parallel to each other; and a cutting step of slicing a SiC ingot obtained in the crystal growth step.

### Advantageous Effects of Invention

According to the SiC wafer of the aspect of the present invention, a defect that becomes a cause of failure of a semiconductor device can be identified in a nondestructive manner after device construction.

According to the manufacturing method of a SiC wafer of the aspect of the present invention, it is possible to obtain the SiC wafer in which a defect that becomes a cause of failure of a semiconductor device can be identified in a nondestructive manner after device construction.

### BRIEF DESCRIPTION OF DRAWINGS

FIG. 1 is a schematic sectional view of a SiC wafer according to an embodiment of the present invention.

FIG. 2 is a view schematically illustrating a section of an example of a semiconductor device constructed using the SiC wafer according to the embodiment of the present invention.

FIG. 3 is a view schematically illustrating a section of an example of a semiconductor device constructed using a SiC wafer in which threading dislocations are not exposed on both a first surface and a second surface.

FIG. 4 is a transmission X-ray topographic picture of a SiC wafer.

### DESCRIPTION OF EMBODIMENTS

Hereinafter, an embodiment will be described in detail with reference to the drawings as appropriate. In the drawings used in the following description, in order to facilitate understanding of the features of the present invention, there are cases where characteristic portions are enlarged for convenience, and the dimensional ratio and the like of each constituent element may be different from reality. In addition, the materials, dimensions, and the like shown in the following description are merely examples, and the present invention is not limited thereto and can be embodied in appropriately modified manners in a range that does not change the gist thereof.

(SiC Wafer)

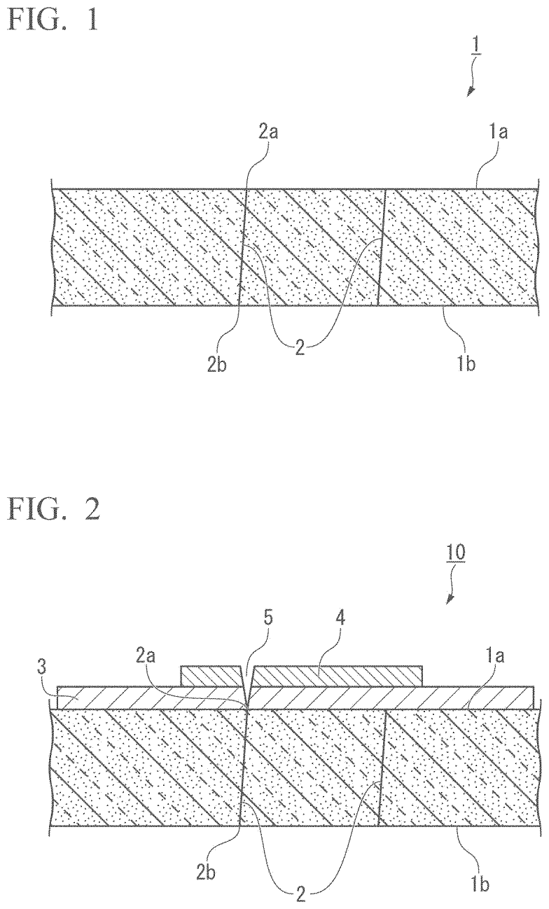

FIG. 1 is a schematic sectional view of a SiC wafer according to an embodiment of the present invention. A SiC wafer 1 illustrated in FIG. 1 has threading dislocations 2 penetrating a first surface 1a and a second surface 1b.

The SiC wafer 1 typically uses a c-plane: (0001) plane as its principal plane. In the SiC wafer 1 illustrated in FIG. 1, the first surface 1a is a surface on the crystal growth direction side and the second surface 1b is a surface opposite to the first surface 1a. Here, the “surface on the crystal growth direction side” means the surface on a side where a crystal has grown after an ingot growth process. That is, in the SiC wafer 1 illustrated in FIG. 1, an ingot before cutting the SiC wafer 1 grows from the second surface 1b side toward the first surface 1a side.

The SiC wafer 1 is not limited to the case of FIG. 1. The first surface 1a may be on a Si-face {0001} plane or a C-face {000-1} plane.

The threading dislocations 2 penetrate the SiC wafer 1 in the thickness direction and are exposed on both the first surface 1a and the second surface 1b. The threading dislocations 2 extend in a direction perpendicular to the c-plane of the SiC wafer 1. In a case of a SiC wafer obtained by cutting a SiC ingot produced from a seed crystal using step-flow growth, the threading dislocations 2 penetrate with a slight inclination with respect to the first surface 1a and the second surface 1b of the SiC wafer 1 as illustrated in FIG. 1. On the other hand, in a case of a SiC wafer obtained by cutting a SiC ingot grown from a just surface having no offset angle, the threading dislocations 2 penetrate in a direction perpendicular to the first surface 1a and the second surface 1b of the SiC wafer 1.

In either case, the threading dislocations 2 are exposed on the first surface 1a and the second surface 1b. That is, threading dislocations 2a exposed on the first surface 1a and threading dislocations 2b exposed on the second surface 1b merely look like the same threading dislocations 2 on different surfaces and have a corresponding relationship.

FIG. 2 is a view schematically illustrating a section of an example of a semiconductor device constructed using the SiC wafer according to the embodiment of the present invention. Here, as an example, a case where C face epitaxial growth is performed on the first surface 1a to form a semiconductor device will be described.

A semiconductor device 10 illustrated in FIG. 2 has an oxide insulating layer 3 formed on the first surface 1a of the SiC wafer 1 described above, and an electrode 4 formed on the surface of the oxide insulating layer 3 on the side opposite to the SiC wafer.

For example, in the semiconductor device 10 illustrated in FIG. 2, in a case where a portion of the threading dislocation 2a exposed on the first surface 1a is a killer defect which becomes a cause of failure of the semiconductor device 10, the thickness of the oxide insulating layer 3 formed on the killer defect may vary. Furthermore, when a voltage is applied to the electrode 4 formed on the oxide insulating layer 3, voltage concentration occurs in a portion where the film thickness of the oxide insulating layer 3 is small, and a short circuit of the element occurs, which may cause a failure defect 5.

That is, the failure defect 5 is formed at a position corresponding to the threading dislocation 2a exposed on the first surface 1a of the SiC wafer 1.

As described above, in the semiconductor device 10 using the SiC wafer according to the embodiment of the present invention, the failure defect 5 and the threading dislocation 2a exposed on the first surface 1a have a corresponding relationship, and the threading dislocation 2a exposed on the first surface 1a and the threading dislocation 2b exposed on the second surface 1b have a corresponding relationship. In other words, the cause of the failure defect 5 can be traced back to the threading dislocation 2b which is exposed on the second surface 1b. As a result, by identifying the threading dislocation 2b exposed on the second surface 1b by non-destructive measurement such as X-ray topography on the second surface 1b, it is possible to trace the history in which a killer defect which becomes a cause of failure is formed.

In the semiconductor device 10 illustrated in FIG. 2, the case where the oxide insulating layer 3 and the electrode 4 are formed on the first surface 1a is described. However, a killer defect can also be traced in the same manner even in a case where the oxide insulating layer 3 and the electrode 4 are formed on the second surface 1b. The epitaxial growth to form the semiconductor device may be either C-face epitaxial growth or Si-face epitaxial growth.

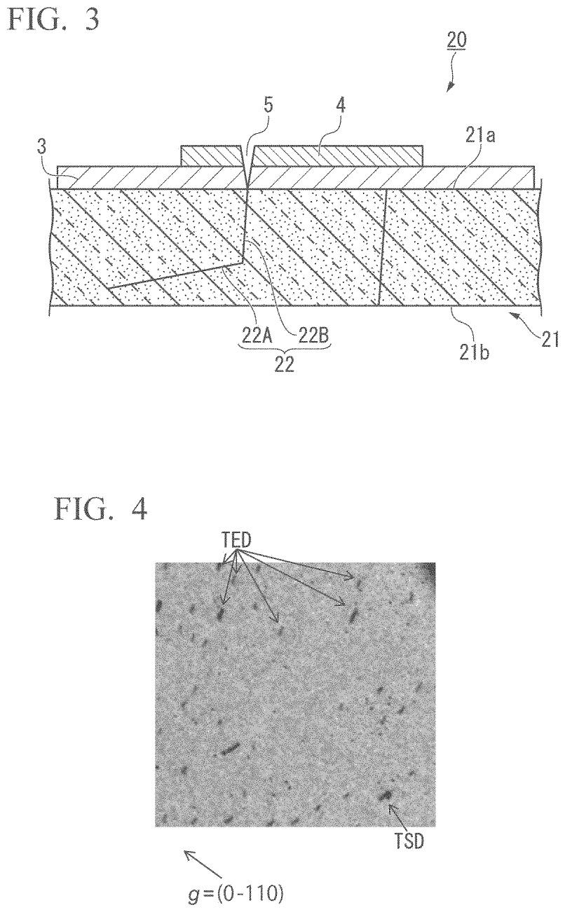

Contrary to this, like a SiC wafer 21 included in a semiconductor device 20 illustrated in FIG. 3, there is a case where threading dislocations 22 are not exposed to both a first surface 21a and a second surface 21b. In this case, a killer defect cannot be traced. The threading dislocation 22 as illustrated in FIG. 3 is generated by conversion of a basal plane dislocation 22A into a threading dislocation 22B.

That is, in the SiC wafer 1 according to the embodiment of the present invention, most of threading dislocations exposed on the first surface 1a are the threading dislocations 2 extending to the second surface 1b, and defects which become the cause of the failure defect 5 of the semiconductor device 10 can be traced in a nondestructive manner.

The difference between the threading dislocation density of threading dislocations exposed on the first surface 1a and the threading dislocation density of threading dislocations exposed on the second surface 1b is 10% or less of the threading dislocation density of the surface with a higher threading dislocation density among the first surface 1a and the second surface 1b. Furthermore, the difference is preferably 5% or less, and more preferably 1% or less of the threading dislocation density of the surface with a higher threading dislocation density among the first surface 1a and the second surface 1b.

When the difference between the threading dislocation density of threading dislocations exposed on the first surface 1a and the threading dislocation density of threading dislocations exposed on the second surface 1b is within the above range, it can be postulated that the threading dislocations exposed on the first surface 1a and the threading dislocations exposed on the second surface 1b have a correlation with each other.

On the other hand, it cannot be said that the threading dislocations exposed on the first surface 1a and the threading dislocations exposed on the second surface 1b have a correlation with each other only because the difference between the threading dislocation density of the threading dislocations exposed on the first surface 1a and the threading dislocation density of the threading dislocations exposed on the second surface 1b is satisfied. This is because there is a case where the threading dislocation densities of both surfaces are close to each other even if there is no correlation therebetween.

Therefore, among the threading dislocations in the SiC wafer, the proportion of the threading dislocations 2 penetrating the first surface 1a and the second surface 1b is 90% or more, preferably 95% or more, and even more preferably 99% or more. Here, the threading dislocations in the SiC wafer can be treated as the same in number as the threading dislocations exposed on the surface with a higher threading dislocation density among the first surface 1a and the second surface 1b.

As described above, since the threading dislocations 2 connect the first surface 1a to the second surface 1b, the cause of the failure defect 5 can be traced. On the other hand, when most of the threading dislocations 2a exposed on the first surface 1a have a corresponding relationship, the history of the failure defect 5 can be sufficiently traced even if some of the threading dislocations 22 in FIG. 3 remain. Therefore, when the proportion of the threading dislocations 2 penetrating the first surface 1a and the second surface 1b in all the threading dislocations in the SiC wafer is within the above-mentioned range, many threading dislocations in the SiC wafer can be traced, and the cause of the failure defect 5 can be found.

In the SiC wafer 1, it is preferable that the number of the threading dislocations 2a exposed on the first surface 1a and the number of threading dislocations 2b exposed on the second surface 1b be substantially the same. Here, “substantially the same” does not need to be exactly the same, and allows a difference of about 0.02 threading dislocations/mm². As described above, since the threading dislocations 2 connect the first surface 1a to the second surface 1b, the cause of the failure defect 5 can be traced. That is, when the number of the threading dislocations 2a of the first surface 1a and the number of the threading dislocations 2b of the second surface 1b are substantially the same, it is possible to trace the cause. In terms of tracing all results, it is preferable that the numbers be exactly the same.

It can be confirmed from an X-ray topographic image of a wafer that threading dislocations penetrate the wafer. FIG. 4 is a transmission X-ray topographic picture of a wafer actually manufactured. In the image, the positions of threading edge dislocations (TEDs) and threading screw dislocations (TSDs) are indicated by arrows. There is a possibility that the threading screw dislocation (TSDs) in the figure may be a mixed dislocation of a threading screw dislocation and an edge dislocation, but is a threading dislocation in any case. Other black dots are other than the threading dislocations, such as basal plane dislocations. Since the image shown in FIG. 4 is seen through the entire thickness direction of the wafer, when a threading dislocation converts or disappears partway, the threading dislocation is identified by its shape such as a V shape. In this image, the threading dislocations are shown as short beard-like contrasts, and these threading dislocations do not interact or combine with the basal plane dislocations or do not disappear. That is, the threading dislocations pass through the inside of the wafer.

The threading dislocations exposed on the first surface 1a and the second surface 1b of the SiC wafer 1, the basal plane dislocations other than the threading dislocations, and the like are distinguished and observed based on the lengths in the transmission X-ray topographic picture. The basal plane dislocations extend in the a-axis direction in the wafer and are thus observed in a string form longer than the threading dislocations in the picture. The transmission topographic image is the simplest method to observe dislocations. However, there is a case where it is difficult to determine whether or not the dislocations are exposed. In such a case, it is possible to determine whether or not dislocations observed are inside the substrate or are exposed, by a method such as section topography. Alternatively, reflection topography using X-rays with high surface resolution and low energy may also be used. Specifically, there is a method of photographing a diffraction surface of (11-28) by using Cu Kα rays using radiation.

In addition, in the SiC wafer 1, the density of the threading dislocations 2 exposed on the surface with a higher threading dislocation density among the first surface 1a and the second surface 1b is preferably 1.5 threading dislocations/mm² or less, more preferably 0.8 threading dislocations/mm² or less, and even more preferably 0.15 threading dislocations/mm² or less.

The threading dislocation densities of the first surface 1a and the second surface 1b of the SiC wafer 1 are calculated as follows. That is, regarding the first surface 1a and the second surface 1b of the SiC wafer 1, observation points in a range of 500 μm×500 μm are selected to pass through the center of the wafer in the form of straight lines at intervals of 5 mm. Furthermore, even in a direction in which the straight lines are rotated by 90°, observation points are also selected to pass through the center of the wafer in the form of straight lines at intervals of 5 mm. Threading dislocations in each range are counted using the X-ray topographic image so that the threading dislocations are distinguished from other basal plane dislocations and the like, and the average value of threading dislocation densities per area is calculated.

From the threading dislocation density of the first surface 1a and the threading dislocation density of the second surface 1b which are obtained, the difference between the threading dislocation density of the threading dislocations exposed on the first surface 1a and the threading dislocation density of the threading dislocations exposed on the second surface 1b can be calculated.

The threading dislocations penetrating the substrate do not necessarily extend vertically due to the difference in the mode of growth, the presence of an offset angle, and the like and may be bent in the substrate sometimes. In other words, it is necessary to reduce the threading dislocation densities to some extent in order to specify whether or not the threading dislocation observed from the rear surface is coincident with a failed portion of the surface. Furthermore, overlaps between dislocations have to be almost completely absent. From this viewpoint, the threading dislocation density which can be used in this application is 1.5 threading dislocations/mm².

The fact, that the density of the threading dislocation exposed on the surface with a higher threading dislocation density among the first surface 1a and the second surface 1b in the SiC wafer 1 is high, means that the probability that the threading dislocations may be combined and disappear during crystal growth increases. When the absolute amount of threading dislocations which are combined and disappear increases, the proportion of the threading dislocations penetrating the first surface 1a and the second surface 1b among all the threading dislocations 2 tends to be low. In addition, the total number of threading dislocations also increases, which results in a difficulty in making correspondence between the first surface 1a and the second surface 1b.

On the other hand, when the density of the threading dislocations 2 is sufficiently small, the corresponding relationship between the threading dislocations 2a and 2b respectively exposed on the first surface 1a and the second surface 1b can be taken without fail. That is, the cause of generating the failure defect 5 can be accurately traced. In addition, the probability that the threading dislocations may be combined and disappear decreases, so that the proportion of the threading dislocations 2 penetrating the first surface 1a and the second surface 1b among all the threading dislocations can be increased.

In addition, the difference between the threading dislocation density exposed on the first surface 1a and the threading dislocation density exposed on the second surface 1b is preferably 0.02 threading dislocations/mm² or less, and more preferably 0.002 threading dislocations/mm² or less.

As the numbers of the threading densities exposed on the first surface 1a and the second surface 1b are close to each other, it means that the number of threading dislocations newly generated is small. That is, it means that threading dislocations other than defects traced are not generated nor disappear.

Considering the process of actual defect tracing, it is conceivable to first measure the threading dislocation densities exposed on the first surface 1a and the second surface 1b, and check the presence or absence of the difference in threading dislocation density. This is because in a case where the measured threading dislocation densities are significantly different from each other, this suggests that the possibility that the proportion of the threading dislocations 2 penetrating the first surface 1a and the second surface 1b may decrease increases, and it can be determined that the SiC wafer is not a SiC wafer suitable for tracing the cause of the defect. That is, when the difference between the threading dislocation density exposed on the first surface 1a and the threading dislocation density exposed on the second surface 1b is small, it can be easily determined that the SiC wafer is a SiC wafer suitable for tracing the cause of the defect, so that the efficiency of tracing the cause of the defect can be increased.

As described above, by using the SiC wafer according to the embodiment of the present invention, a defect which becomes a cause of failure in the semiconductor device can be identified in a nondestructive manner after device construction.

(Manufacturing Method of SiC Wafer)

A manufacturing method of a SiC wafer according to the embodiment of the present invention includes a preparation step of producing a seed crystal having a surface density of threading dislocations of 1.5 threading dislocations/mm² or less, a crystal growth step of performing crystal growth so that the diameter of the crystal does not increase from the seed crystal in a crucible and a crystal growth surface and isotherms in the crucible are parallel to each other, and a cutting step of slicing a SiC ingot obtained in the crystal growth step.

<Preparation Step>

First, the seed crystal is prepared as the preparation step. The seed crystal is obtained by the repeated a-face (RAF) method. The RAF method is a method of performing c-plane growth after performing a-plane growth at least once. By using the RAF method, it is possible to produce a SiC single crystal having substantially no screw dislocations and stacking fault. This is because defects included in the SiC single crystal after the a-plane growth become defects in a basal plane direction during the c-plane growth and are not succeeded. Details of the RAF method are described in, for example, Japanese Unexamined Patent Application, First Publication No. 2003-321298.

In addition, the crystal grown in the RAF method may be used as a seed crystal, c-plane ((0001) plane) may further be performed thereon to produce a crystal with a reduced number of threading dislocations, and the crystal may be used as the seed crystal. As the crystal growth proceeds, the threading dislocations are combined and the threading dislocation density thereof decreases. That is, by sufficiently performing the crystal growth in the crystal growth step, the threading dislocation density can be further reduced. As a result, variation in the number of threading dislocations can be further reduced in the crystal growth process, so that a desired SiC wafer can be more easily and reliably obtained.

The seed crystal produced in this procedure has extremely few or no threading dislocations.

The surface density of the threading dislocations in the seed crystal is preferably 1.5 threading dislocations/mm² or less, more preferably 0.8 threading dislocations/mm² or less, and even more preferably 0.15 threading dislocations/mm² or less. When the number of threading dislocations in the seed crystal is small, the number of threading dislocations in the first surface and the second surface of the SiC wafer can be easily caused to be constant.

The surface density of the threading dislocations in the seed crystal may satisfy at least the above range on the surface on which the SiC ingot grows. In addition, the surface density of the threading dislocations in the seed crystal is measured in the same manner as the threading dislocation densities of the first surface 1a and the second surface 1b of the SiC wafer 1.

The threading dislocations in the seed crystal may be combined in the crystal growth process to obtain a SiC ingot from the seed crystal and may decrease in number. When the threading dislocation density in the seed crystal is high, the probability that the threading dislocations may be combined in the crystal growth process increases. When the number of threading dislocations in the crystal growth process varies, this tends to cause a difference in the number of threading dislocations between the first surface and the second surface of the SiC wafer obtained by slicing the SiC ingot.

Contrary to this, when the threading dislocation density of the initial seed crystal is sufficiently small, the probability that the threading dislocations may be combined can be reduced. That is, the number of threading dislocations in the first surface and the second surface of the SiC wafer can be easily caused to be constant. When a seed crystal having 0.15 threading dislocations/mm² or less of threading dislocations is used, combination and disappearance thereof do not substantially occur. Therefore, regarding the threading dislocations caused by the seed crystal, the numbers of threading dislocations exposed on the first surface and the second surface of the SiC wafer can be caused to be substantially the same.

<Crystal Growth Step>

Next, crystal growth is performed based on the obtained seed crystal to produce a SiC ingot. In the crystal growth step, the cause of variation in the number of threading dislocations is not limited to the combination of the threading dislocations, and conversion of threading dislocations into basal plane dislocations or the like is also one of causes.

Therefore, in the crystal growth step, crystal growth is performed to suppress conversion of threading dislocations into basal plane dislocations or the generation of new threading dislocations, in addition to suppressing the combination of threading dislocations. In order to suppress variation in the number of threading dislocations in the crystal growth step, crystal growth is performed with attention to the following points.

The first point is that the diameter of the crystal is not increased during crystal growth. In recent years, there has been a demand for an increase in the diameter of a SiC wafer in order to obtain many semiconductor devices from a single substrate, so that a crystal is generally increased in diameter using a tapered guide. The tapered guide refers to a cone-shaped member which increases in diameter from a seed crystal toward a SiC source when a SiC crystal is grown by a sublimation method. When the tapered guide is used, the SiC crystal grows along the taper, so that the diameter can be increased by controlling the shape of the growth surface to a convex shape.

However, when the diameter is increased, conversion of threading dislocations into basal plane dislocations tends to occur particularly in an end portion of the SiC ingot. That is, when the diameter is increased, the number of threading dislocations tends to vary during the crystal growth, and it becomes difficult to easily cause the numbers of threading dislocations in the first surface and the second surface of the SiC wafer to be constant.

Therefore, in the manufacturing method of a SiC wafer according to the embodiment of the present invention, the diameter is not increased. As a method that does not cause an increase in diameter, there is a method of using a cylindrical guide with a constant diameter instead of the cone-shaped tapered guide.

The second point is that crystal growth is performed so that the crystal growth surface and the isotherms in the crucible become parallel to each other. In the growth process, when the crystal growth surface is curved, as in the case where the diameter is increased, conversion of threading dislocations into basal plane dislocations tends to occur in the end portion. That is, it is preferable that the crystal growth surface during the crystal growth be made as flat as possible.

Crystal growth is greatly affected by the temperature during crystal growth. Therefore, a flat crystal growth surface can be maintained by setting the isotherms to be parallel to the crystal growth surface. The isotherms do not need to be perfectly parallel to the crystal growth surface and may be substantially parallel thereto. More specifically, it is preferable to perform crystal growth so that the inclination angle of the isotherms with respect to the crystal growth surface is less than 20 in terms of absolute value in any direction.

As a method of causing the isotherms to be parallel to the crystal growth surface in a temperature distribution during crystal growth, a method disclosed in Japanese Unexamined Patent Application, First Publication No. 2008-290885 can be used. Specifically, a sublimation method crystal growth apparatus having a configuration in which two upper and lower heaters including a heater facing a side plane of a place where a seed crystal is disposed and a heater facing a side plane of a place where a source is disposed are provided and a partition wall portion formed of a heat insulation member is provided between the upper and lower heaters can be used. The partition wall portion prevents transfer of heat from the lower heater toward the upper side of the crucible and thus the isotherms can be caused to be parallel to the surface of the seed crystal.

During crystal growth by the sublimation method, when growth is performed while periodically changing a nitrogen (N) doping amount, the growth surface has a stripe pattern due to the difference in nitrogen (N) concentration. This is sliced in the longitudinal sectional direction, and the shape of the growth surface at each time can be obtained from the interface with color changes. In a case where the growth surface changes during the growth, the shape of the growth surface can be maintained through adjustment according to the following method.

Maintaining the isotherms during crystal growth can be realized by further combining other techniques. Specifically, a crucible is moved during growth so that a change in the growth surface shape obtained in advance in the above-described method is corrected, and a technique in which the isotherms and a growth surface height are caused to be coincident with each other is combined.

First, a partition wall portion formed of a heat insulation material is provided between a high-temperature region and a low-temperature region to achieve a temperature distribution in which the isotherms are parallel to the surface of the seed crystal at the time of the start of growth. Thereafter, the growth surface height at each time is inferred from growth results under the same conditions confirmed in advance, whereby growth is performed while controlling the growth surface height to be the same height with respect to the partition wall portion formed of the heat insulation material. Then, the angle of the isotherms can be maintained so as to be parallel to the surface of the seed crystal.

Furthermore, a method of using a cylindrical guide may be combined with the method of causing the isotherms to be parallel to the surface of the seed crystal. This method has a great effect. The cylindrical guide being parallel to the crucible in the vertical direction thus easily causes the isotherms to be parallel to the surface of the seed crystal compared to a guide having an inclination for an increase in diameter.

In addition, dislocations of SiC may proliferate when the stress in a crystal during growth is large. When the temperature gradient in the vicinity of the crystal during growth increases, stress in the crystal increases. As the temperature gradient in the vicinity of the crystal, there are a temperature gradient in the growth direction (growth axis direction) and a temperature gradient in the radial direction. The temperature gradient in the radial direction can be reduced by causing the isotherms to be parallel to the surface of the seed crystal using an apparatus having a partition wall portion and upper and lower heaters as described above. The temperature gradient in the growth axis direction can be reduced by reducing the temperature difference between the seed crystal and the source. When the temperature gradient is too small, growth becomes unstable, so that it is preferable that the temperature gradient in the growth axis direction be about 50 Kcm¹. By controlling both the temperature gradient in the growth axis direction and the temperature gradient in the radial direction to small values in a range in which stable growth can be achieved, the proliferation of dislocations due to the stress can be suppressed.

In addition, there are cases where the growth atmosphere becomes C-rich, carbon inclusions occur, and dislocations caused therefrom are generated. The generation of dislocations caused by the carbon inclusions can be suppressed by determining whether or not the growth atmosphere is C-rich from the defect state and adjusting the conditions. As a method of preventing the growth atmosphere from becoming C-rich, a method of adding and supplying Si in addition to SiC to the source, a method of covering the crucible wall with a TaC member or the like, and the like can be adopted.

As described above, by maintaining the isotherms without an increase in diameter and performing crystal growth while suppressing the generation of new threading dislocations, variation in threading dislocations in the crystal growth step can be reduced. As a result, the number of threading dislocations in the first surface and the second surface of the SiC wafer can be easily caused to be constant.

<Cutting Step>

Last, the obtained SiC ingot is cut. A known method can be used to cut the SiC ingot. For example, a wire saw or the like can be used.

As described above, according to the manufacturing method of a SiC wafer of the embodiment of the present invention, it is possible to obtain a SiC wafer in which a defect that becomes a cause of failure of a semiconductor device can be identified in a nondestructive manner after device construction.

While the preferred embodiments of the present invention have been described above in detail, the present invention is not limited to the specific embodiments, and various changes and modifications can be made without departing from the scope of the present invention described in the claims.

### REFERENCE SIGNS LIST

1, 21: SiC wafer
1a, 21a: first surface
1b, 21b: second surface
2, 2a, 2b, 22, 22B: threading dislocation
3: oxide insulating layer
4: electrode
5: failure defect
10, 20: semiconductor device
22A: basal plane dislocation

1. A SiC wafer, wherein
a difference between a threading dislocation density of threading dislocations exposed on a first surface and a threading dislocation density of threading dislocations exposed on a second surface is 10% or less of the threading dislocation density of the surface with a higher threading dislocation density among the first surface and the second surface, and
90% or more of the threading dislocations exposed on the surface with a higher threading dislocation density among the first surface and the second surface extend to the surface with a lower threading dislocation density.

2. The SiC wafer according to claim 1,
wherein the numbers of the threading dislocations of the first surface and the second surface are substantially the same.

3. The SiC wafer according to claim 1,
wherein a density of the threading dislocations exposed on the surface with a higher threading dislocation density among the first surface and the second surface is 1.5 threading dislocations/mm² or less.

4. The SiC wafer according to claim 1,
wherein the difference between the threading dislocation density exposed on the first surface and the threading dislocation density exposed on the second surface is 0.02 threading dislocations/mm² or less.

5. A manufacturing method of a SiC wafer, comprising:
a preparation step of producing a seed crystal having a surface density of threading dislocations of 1.5 threading dislocations/mm² or less;
a crystal growth step of performing crystal growth so that a diameter of a crystal does not increase from the seed crystal in a crucible and a crystal growth surface and an isotherms in the crucible are parallel to each other; and
a cutting step of slicing a SiC ingot obtained in the crystal growth step.

6. The SiC wafer according to claim 2,
wherein a density of the threading dislocations exposed on the surface with a higher threading dislocation density among the first surface and the second surface is 1.5 threading dislocations/mm² or less.

7. The SiC wafer according to claim 2,
wherein the difference between the threading dislocation density exposed on the first surface and the threading dislocation density exposed on the second surface is 0.02 threading dislocations/mm² or less.

8. The SiC wafer according to claim 6,
wherein the difference between the threading dislocation density exposed on the first surface and the threading dislocation density exposed on the second surface is 0.02 threading dislocations/mm² or less.
